(19) United States
(12) Patent Application Publication
(10) Pub. No.: US 2025/0375879 A1
(43) Pub. Date: Dec. 11, 2025

(54) ROBOT SYSTEM, ROBOT CONTROL METHOD, AND ROBOT CONTROL PROGRAM

(71) Applicant: KAWASAKI JUKOGYO KABUSHIKI KAISHA, Kobe-shi, Hyogo (JP)

(72) Inventors: Takeshi SHIBATA, Kobe-shi (JP); Ryota ONO, Kobe-shi (JP)

(73) Assignee: KAWASAKI JUKOGYO KABUSHIKI KAISHA, Kobe-shi, Hyogo (JP)

(21) Appl. No.: 18/879,973

(22) PCT Filed: Jul. 4, 2023
(86) PCT No.: PCT/JP2023/024839

§ 371 Date: Dec. 30, 2024

(30) Foreign Application Priority Data
Jul. 5, 2022 (JP) 2022-108324

(51) Int. Cl. B25J 9/16; B25J 9/12

(52) U.S. Cl. CPC B25J 9/1633; B25J 9/12

(57) ABSTRACT

A robot system includes: a robot including a hand that holds a workpiece and a robot arm to which the hand is coupled; and a controller that moves the robot arm to perform position control of the hand. The controller corrects a target height of the hand in the position control depending on the workpiece held by the hand.

### FIELD

The technique disclosed here relates to a robot system, a robot control method, and a robot control program.

### BACKGROUND

A robot system known to date moves a hand holding a workpiece with a robot arm. A robot system disclosed in Patent Document 1 corrects an endpoint position of a robot, taking into account deflection of the robot. Specifically, the robot system corrects an endpoint position of the robot in consideration of changes of deflection of the robot in accordance with a posture of the robot.

### CITATION LIST

### Patent Document

Patent Document 1: Japanese Patent Application Publication No. H04-233602

### SUMMARY

As described above, the system that transfers a workpiece with the robot arm can increase position accuracy of the hand by considering deflection of the robot arm and other factors. The deflection of the robot, however, also varies based on factors other than the posture of the robot. That is, there is still room for further improvement in position accuracy of the hand.

It is therefore an object of the technique disclosed here to enhance position accuracy of a hand in a robot arm.

A robot system according to the present disclosure includes: a robot including a hand that holds a workpiece, and a robot arm to which the hand is coupled; and a controller that moves the robot arm to perform position control of the hand, wherein the controller corrects a target height of the hand in the position control depending on the workpiece held by the hand.

A robot control method according to the present disclosure includes: moving a robot arm to which a hand that holds a workpiece is coupled to perform position control of the hand; and correcting a target height of the hand in the position control depending on the workpiece held by the hand.

A robot control program according to the present disclosure is a robot control program for causing a computer to perform the function of controlling a robot including a hand that holds a workpiece and a robot arm to which the hand is coupled, and the program causes the computer to perform the functions of: moving the robot arm to perform position control of the hand; and correcting a target height of the hand in the position control depending on the workpiece held by the hand.

The robot system can enhance position accuracy of the hand in the robot arm.

The robot control method can enhance position accuracy of the hand in the robot arm.

The robot control program can enhance position accuracy of the hand in the robot arm.

### BRIEF DESCRIPTION OF THE DRAWINGS

FIG. 1 is a schematic view illustrating a robot system.

FIG. 2 is a schematic plan view of the robot system installed in a clean room.

FIG. 3 is a schematic hardware configuration of a controller.

FIG. 4 is a functional block diagram illustrating a configuration of a control system of a processor in the controller.

FIG. 5 is a schematic view illustrating a workpiece in a first box or a second box.

FIG. 6 is a flowchart of a transfer action.

FIG. 7 is a graph showing a motor current to a first electric motor and a height of a hand.

FIG. 8 is a schematic view for describing the hand in an elevation action.

FIG. 9 is a graph showing a motor current to the first electric motor and a height of the hand during a transfer action in a case where a target height of the hand is not corrected.

### DESCRIPTION OF EMBODIMENTS

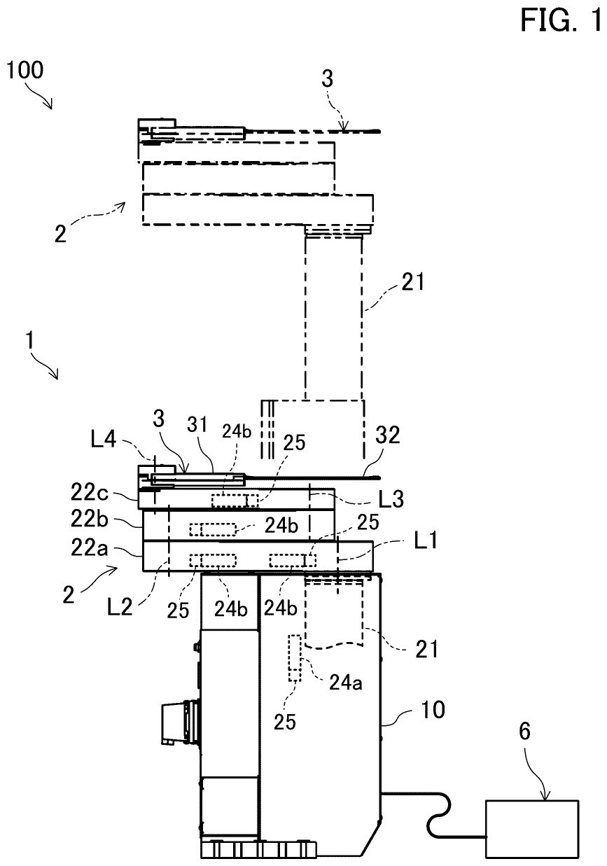

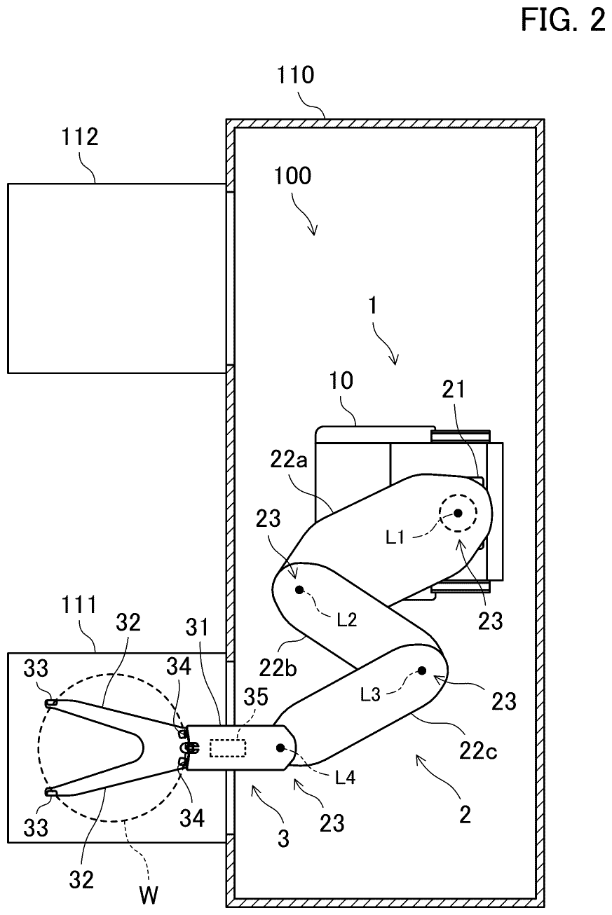

An exemplary embodiment will be described in detail hereinafter with reference to the drawings. FIG. 1 is a schematic view illustrating a robot system 100. FIG. 2 is a schematic plan view of the robot system 100 installed in a clean room 110.

The robot system 100 includes a robot 1 and a controller 6 that controls the robot 1. The robot 1 includes a hand 3 that holds a workpiece W, and a robot arm 2 to which the hand 3 is coupled. The robot 1 is a so-called horizontal articulated robot and is a robot of a selective compliance assembly robot arm (SCARA) type. The robot 1 may further include a base 10 to which the robot arm 2 is coupled. The hand 3 is a so-called end effector. The controller 6 moves the robot arm 2 to perform position control of the hand 3, that is, position control of the workpiece W.

The robot 1 handles various types of workpieces. That is, the hand 3 holds any one of various types of workpieces W. Examples of the workpieces W include a substrate. The substrate can be a thin film that can be a material for a substrate of a semiconductor device, such as a semiconductor substrate (i.e., semiconductor wafer) and a glass substrate (i.e., glass wafer). Examples of the semiconductor substrate include a silicon substrate and a sapphire substrate. Examples of the glass substrate include a glass substrate for a flat panel display (FPD) and a glass substrate for a micro electro mechanical system (MEMS). In a case where the workpiece W is a substrate, the robot 1 can handle various types of substrates. The robot 1 can handle substrates of different sizes such as 200 mm, 300 mm, and 450 mm, as workpieces W. The workpieces W include a focus ring, a jig, and an assembly in which a substrate is incorporated in a jig, as well as the substrate. The workpieces W are not limited to these examples, and can include any parts.

### Robot

The robot 1 is, for example, a robot designed for use in clean rooms. The robot 1 is placed and used in a clean room 110. The clean room 110 is defined by peripheral walls, and the interior thereof is maintained in a clean, that is, purified, state. The clean room 110 includes a first box 111 as a first place in which a workpiece W is placed, and a second box 112 as a second place in which a workpiece W is placed.

The robot arm 2 includes an elevator 21 mounted on the base 10 to be movable upward and downward substantially vertically, links 22, joints 23 coupling the links 22 such that the links 22 are rotatable horizontally, electric motors 24 that move the elevator 21 and the links 22, and encoders 25 mounted on the electric motors 24.

The elevator 21 has a columnar shape. While the elevator 21 is fully lowered, most part of the elevator 21 is housed in the base 10. The elevator 21 rises to project upward from the base 10.

The links 22 include a first link 22a, a second link 22b, and a third link 22c. When the first link 22a, the second link 22b, and the third link 22c are not distinguished from one another, these links are referred to simply as “links 22.” The first link 22a is coupled to the elevator 21 through the joint 23 to be rotatable substantially horizontally. The second link 22b is coupled to the first link 22a and the third link 22c through the joints 23 individually to be rotatable substantially horizontally. The hand 3 is coupled to the third link 22c through the joint 23 to be rotatable substantially horizontally.

Specifically, each of the links 22 extends in a predetermined longitudinal direction. Each link 22 has a hollow shape and has an internal space. One end of each link 22 in the longitudinal direction will be referred as a first end, and the other end will be referred to as a second end. The first end of the first link 22a is coupled to the elevator 21 to be rotatable about an axis L1 extending substantially vertically. The first end of the second link 22b is coupled to the second end of the first link 22a to be rotatable about an axis L2 extending substantially vertically. The first end of the third link 22c is coupled to the second end of the second link 22b to be rotatable about an axis L3 extending substantially vertically. The hand 3 is coupled to the second end of the third link 22c to be rotatable about an axis LA extending substantially vertically.

The first link 22a, the second link 22b, the third link 22c, and the hand 3 are stacked in this order from the bottom such that these links and the hand are not in contact with one another. The first link 22a, the second link 22b, the third link 22c, and the hand 3 rotate substantially horizontally without interference with one another.

The hand 3 includes a body 31 and a bifurcated holder 32 coupled to the body 31. The hand 3 has a plate shape. The hand 3 has a substantially Y shape when seen in the thickness direction thereof. The body 31 is coupled to the second end of the third link 22c.

Holding by the hands 3 can be achieved in various forms, such as gripping, suction, placement, or fitting. In this example, the hand 3 grips a workpiece W. Specifically, a nail 33 is fixed to each of the two distal ends of the holder 32. The body 31 includes movable nails 34 and a hold actuator 35 (see FIG. 2) that drives the nails 34. The hold actuator 35 includes, for example, an air cylinder. The hold actuator 35 drives the nails 34 with the air cylinder to thereby switch between holding and releasing of the workpiece W by the hand 3.

The electric motors 24 is, for example, a servo motor. Each of the encoder 25 detects a rotation position or a rotation speed of the corresponding one of the electric motors 24. The electric motors 24 includes a first electric motor 24a for the elevator 21 and second electric motors 24b for the links 22. The first electric motor 24a moves the elevator 21 upward and downward. The first electric motor 24a is accommodated in the base 10. Each of the second electric motors 24b rotationally drives a corresponding one of the joints 23. The second electric motors 24b are accommodated in internal spaces of the links 22.

The controller 6 controls the robot arm 2 and the hand 3 to move the robot 1. In position control, the controller 6 sets target positions of the robot arm 2 and the hand 3, and controls the robot arm 2 and the hand 3 such that the hand 3 is located at the target position. The target position of the hand 3 includes a target height of the hand 3. The controller 6 corrects the target height of the hand 3 in the position control depending on the workpiece W held by the hand 3.

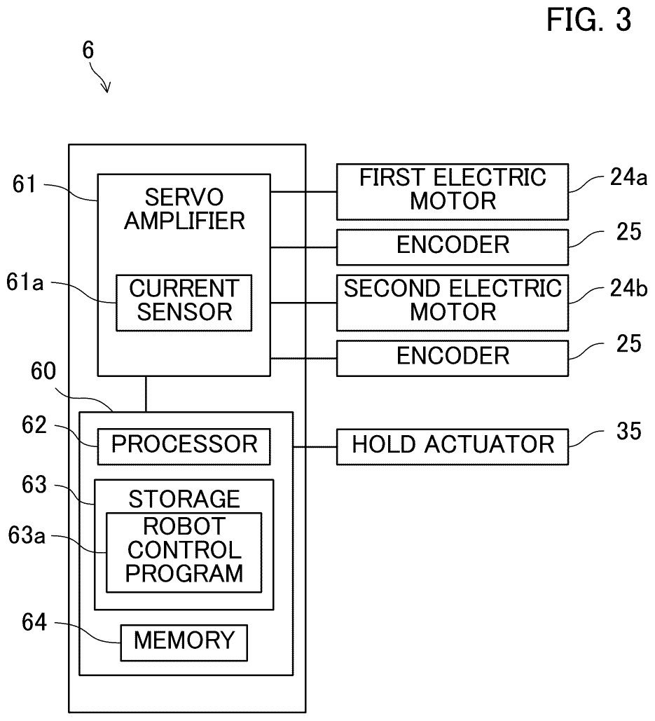

FIG. 3 illustrates a schematic hardware configuration of the control device 6. The controller 6 is, for example, a computer. The electric motors 24, the encoders 25, the hold actuator 35, and other members are connected to the controller 6. Although FIG. 3 shows only one pair, multiple pairs of the second electric motors 24b and the encoders 25 are actually connected to the controller 6. The controller 6 includes a main controller 60 and a servo amplifier 61. The main controller 60 controls the hold actuator 35 and also controls the robot 1 through the servo amplifier 61. For example, the main controller 60 controls a solenoid valve for switching air supply to the air cylinder of the hold actuator 35 to thereby switch between holding and releasing the workpiece W by the hand 3. The main controller 60 outputs a rotation position, a rotation speed, or an instruction value concerning a rotation torque of each of the electric motors 24 of the robot 1, to the servo amplifier 61. The servo amplifier 61 applies a motor current in accordance with the instruction value from the main controller 60, to each electric motor 24. The servo amplifier 61 includes a current sensor 61a that detects a motor current applied to each of the electric motors 24. At this time, the servo amplifier 61 performs feedback control on the motor current based on a detection result of each encoder 25. In this manner, the controller 6 moves the hand 3 to the target position or moves the hand 3 at a target speed or a target acceleration.

As an example, the controller 6 controls the electric motors 24 and the hold actuator 35 to thereby cause the robot 1 to perform a transfer action. Specifically, in the controller 6, target positions, that is, a target trajectory, of the hand 3 during the transfer action are set beforehand. The main controller 60 outputs instruction values corresponding to the target positions of the hand 3, that is, target rotation positions of each electric motor 24, to the servo amplifier 61. The servo amplifier 61 applies motor currents corresponding to the instruction values to each electric motor 24. The servo amplifier 61 performs feedback control on the motor currents based on detection results of the encoder 25 such that the rotation positions of the electric motor 24 coincides with the target rotation positions. In this manner, the main controller 60 controls the electric motors 24 such that the hand 3 is located at the target positions. The main controller 60 moves the hold actuator 35 to switch between holding and releasing of the workpiece W by the hand 3.

The main controller 60 includes a processor 62, a storage 63, and a memory 64.

The processor 62 controls the entire main controller 60. The processor 62 performs various computations. For example, the processor 62 is a processor such as a central processing unit (CPU). The processor 62 may be a unit such as a micro controller unit (MCU), a micro processor unit (MPU), a field programmable gate array (FPGA), a programmable logic controller (PLC), or system LSI.

The storage 63 stores various types of data and programs to be executed by the processor 62. Specifically, the storage 63 stores a robot control program 63a. The storage 63 stores teaching data for operating the robot 1. The storage 63 is a nonvolatile memory, a hard disc drive (HDD), or a solid state drive (SSD).

The memory 64 temporarily stores data or other information. For example, the memory 64 is a volatile memory.

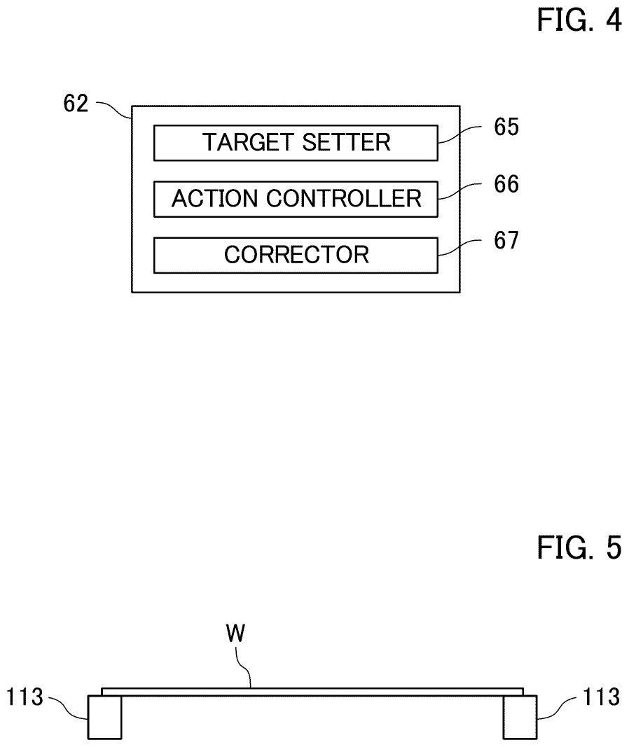

FIG. 4 is a functional block diagram illustrating a configuration of a control system of a processor 62 in the controller 6. The processor 62 reads the robot control program 63a from the storage 63 and develops the program to the memory 64 to thereby operate various functions. Specifically, the processor 62 functions as a target setter 65, an action controller 66, and a corrector 67.

The target setter 65 sets target positions of the robot arm 2 and the hand 3 (hereinafter referred to as “target positions of the robot arm 2 and others”) and target positions of the robot arm 2 and the hand 3 in activating and deactivating the hold actuator 35 (hereinafter referred to as “activation target positions of the hold actuator 35”). The target setter 65 reads teaching data from the storage 63, and generates target positions of the robot arm 2 and others and activation target positions of the hold actuator 35 based on the teaching data. The teaching data can be data corresponding to a target trajectory, that is, target positions, of the robot arm 2 and the hand 3. The teaching data also includes target positions of the robot arm 2 and the hand 3 in activating or deactivating the hold actuator 35. In this example, the teaching data is target rotation positions of each electric motor 24 corresponding to target positions of the robot arm 2 and the hand 3. That is, substantially as the target positions of the robot arm 2 and others and the activation target positions of the hold actuator 35, the target setter 65 sets the target rotation positions of each electric motor 24 corresponding to the target positions and the activation target positions.

The action controller 66 generates and outputs instruction values to the electric motors 24 and the hold actuator 35 based on the target positions set by the target setter 65. Specifically, the action controller 66 outputs the target rotation positions of each electric motor 24 as instruction rotation positions, to the servo amplifier 61. The servo amplifier 61 applies motor currents corresponding to the instruction rotation positions to each electric motor 24. The servo amplifier 61 controls motor currents such that the rotation position of each electric motor 24 coincides with the instruction rotation positions. The action controller 66 outputs activation instructions to the hold actuator 35 at timings when the instruction rotation positions corresponding to the activation target positions of the hold actuator 35 is output to the servo amplifier 61. The hold actuator 35 switches between holding and releasing of the workpiece W based on the activation instructions.

The corrector 67 corrects the target height of the hand 3 in the target positions of the robot arm 2 and the hand 3 set by the target setter 65. In this example, since the target rotation position of each electric motor 24 is set as the target positions, the target rotation position of each electric motor 24 corresponding to the target height of the hand 3 is corrected. Specifically, the corrector 67 corrects the target rotation position of the first electric motor 24a set by the target setter 65. As a result of correction of the target height, the action controller 66 generates an instruction value corresponding to the corrected target height, and outputs the instruction value to the servo amplifier 61. Specifically, the corrector 67 corrects the target height of the hand 3 depending on the workpiece W held by the hand 3. For example, the corrector 67 corrects the target height such that the target height of the hand 3 increases as the weight of the workpiece W increases.

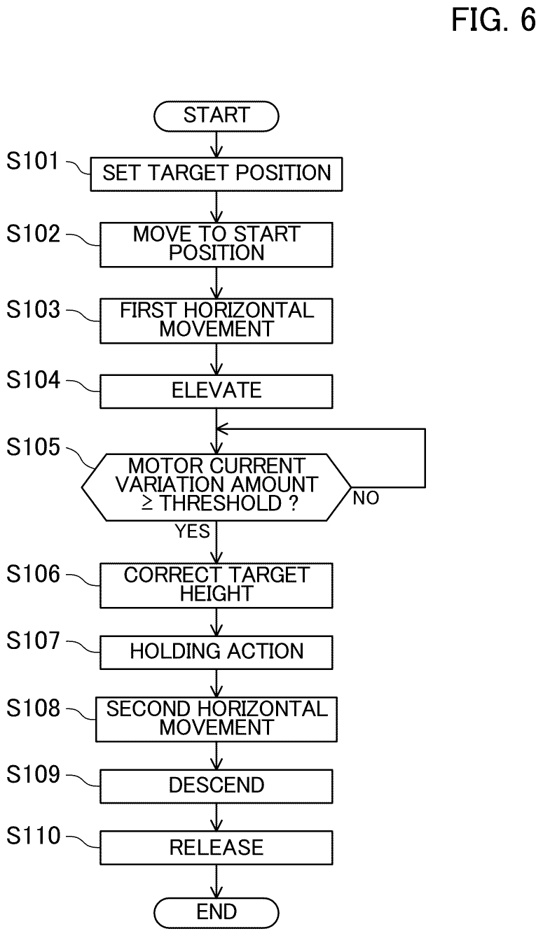

Next, examples of actions of the robot system 100 will be described. For example, the controller 6 causes the robot 1 to perform a transfer action of picking up a workpiece W placed in the first box 111 and transferring the workpiece W to the second box 112. FIG. 5 is a schematic view illustrating a workpiece W in the first box 111 or the second box 112. FIG. 6 is a flowchart of the transfer action.

In this example, as illustrated in FIG. 5, the workpiece W is placed on a stage 113 in the first box 111 or the second box 112. In this example, the workpiece W is simply placed on the stage 113. The stage 113 supports the lower surface of an edge portion of the workpiece W.

First, in step S101, the controller 6 sets target positions of the robot arm 2 and the hand 3. Specifically, based on teaching data stored in the storage 63, the target setter 65 sets a target rotation position of each electric motor 24 corresponding to the target positions of the robot arm 2 and the hand 3 in a transfer action.

Next, in step S102, the controller 6 moves the hand 3 to a predetermined start position. A target height of the hand 3 at the start position is lower than a height of the workpiece W (hereinafter referred to as a “workpiece height Z0”) in the first box 111 and is at a height at which the hand 3 can move into a space under the workpiece W in the first box 111. The target height at the start position will be referred to as a “first target height Z1.” The controller 6 applies a motor current to each electric motor 24 to thereby locate the robot arm 2 and the hand 3 at the start position.

In the case of the robot 1, the first electric motor 24a adjusts the height of the hand 3 and the second electric motors 24b adjusts a horizontal position of the hand 3. FIG. 7 is a graph showing a motor current to the first electric motor 24a and a height of the hand 3. FIG. 7 does not show a motor current to each second electric motor 24b and a horizontal position of the hand 3. The servo amplifier 61 adjusts the motor current to the first electric motor 24a such that the rotation position of the first electric motor 24a coincides with a position corresponding to the first target height Z1. As a result, the actual height of the hand 3 (hereinafter referred to as a “real height”) is adjusted to a height substantially equal to the first target height Z1.

Thereafter, in step S103, the controller 6 causes the robot 1 to perform first horizontal movement. In the first horizontal movement, the robot arm 2 horizontally moves the hand 3 to a space under the workpiece W in the first box 111. The controller 6 controls the second electric motors 24b to thereby move the links 22 and move the hand 3 to a space under the workpiece W in the first box 111. Since the height of the hand 3 remains unchanged during the first horizontal movement, the motor current to the first electric motor 24a hardly changes from when the hand 3 is at the start position, as shown in FIG. 7.

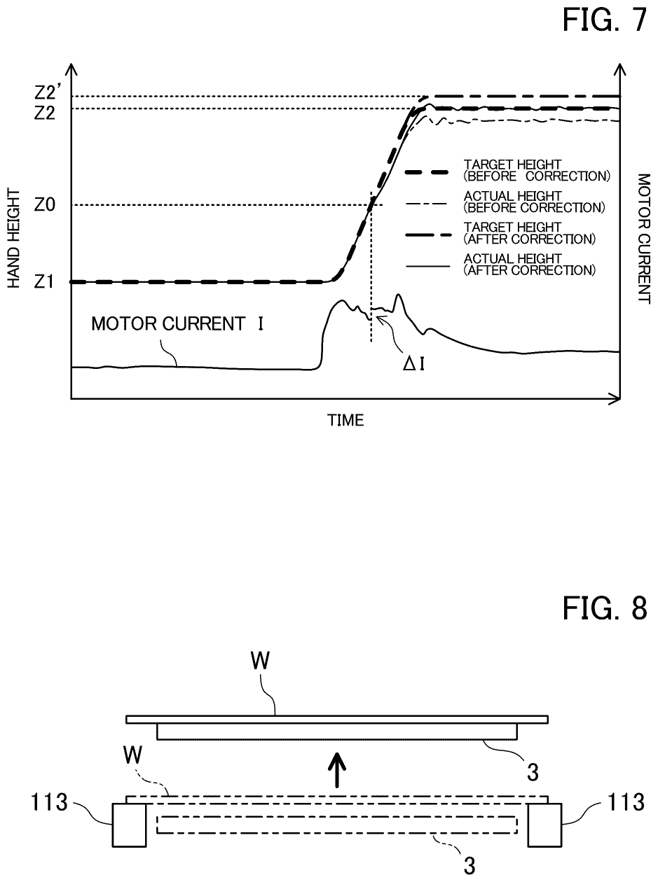

After the hand 3 has moved to the space under the workpiece W in the first box 111, the controller 6 causes the robot 1 to perform an elevation action in step S104. FIG. 8 is a schematic view for describing the hand 3 in the elevation action. In the elevation action, the robot 1 moves the hand 3 upward from the first target height Z1 to a second target height Z2. The second target height Z2 is, for example, higher than the stage 113 in the first box 111. In this example, in the elevation action, the controller 6 causes the robot arm 2 and the hand 3 to perform a constant-speed motion in which the hand 3 elevates at a constant speed. The controller 6 controls an elevation speed of the hand 3 by adjusting a motor current to the first electric motor 24a. The controller 6 increases the motor current until the elevation speed of the hand 3 reaches a predetermined target speed, and when the elevation speed reaches the predetermined target speed, the controller 6 controls the motor current to keep the target speed substantially constant. Step S104 corresponds to the step of moving the robot arm to which a hand that holds a workpiece is coupled to thereby perform position control of the hand.

The controller 6 detects the motor current to the first electric motor 24a with the current sensor 61a in the elevation action. The controller 6 sequentially records detected motor currents, that is, current values (hereinafter referred to as “detected current values”), in the storage 63 or the memory 64. The controller 6 may detect and record a current value of the motor current to the first electric motor 24a in the transfer action as well as in the elevation action.

When the elevation action of the hand 3 continues, the hand 3 passes over the position of the workpiece W while the hand 3 moves from the first target height Z1 to the second target height Z2, as shown in FIG. 8. At this time, the hand 3 picks up the workpiece W from the stage 113. The workpiece W is in the state of being placed on the hand 3. Since the hand 3 elevates at a constant speed at least before and after the hand 3 picks up the workpiece W, the hand 3 picks up the workpiece W with stability.

The controller 6 monitors variations of the motor current to the first electric motor 24a during the elevation action, and in step S105, determines whether the variation amount of the motor current is greater than or equal to a predetermined threshold or not. If the variation amount of the motor current is less than the threshold, the controller 6 repeats step S105. If the variation amount of the motor current is greater than or equal to the threshold, the controller 6 proceeds to step S106 and corrects the target height of the hand 3. Step S106 corresponds to correcting the target height of the hand in the position control depending on the workpiece held by the hand.

Specifically, in the elevation action, the controller 6 obtains an average current value that is a moving average value of the detected current values recorded in the storage 63 or the memory 64. In step S105, the corrector 67 of the controller 6 determines whether the amount of variations of the average current value reaches a predetermined threshold or more in change of the average current value over time. The threshold is a value corresponding to the variation amount of the average current value caused by pickup of the workpiece W by the hand 3. For example, the threshold is a value corresponding to the variation amount of the average current value caused by pickup, by the hand 3, of a most lightweight workpiece W in the workpieces W handled with the robot 1.

If the variation amount of the average current value is less than the threshold, the corrector 67 repeats step S105, and waits until the variation amount of the average current value reaches the threshold or more.

If the variation amount of the average current value is greater than or equal to the threshold, in step S106, the corrector 67 obtains a correction amount ΔZ of the target height of the hand 3 by Equation (1) where an average current value immediately before the variation amount reaches the threshold or more is a first current value Ia, and an average current value when the variation amount reaches the threshold or more is a second current value Ib:

$$Δ Z = K \times ( I b - I a ) \qquad ( 1 )$$

where K is a correction factor and is stored in the storage 63 beforehand. Ib-Ia is a variation amount ΔI of the motor current to the first electric motor 24a caused by pickup of the workpiece W by the hand 3. The variations of the motor current are caused by pickup of the workpiece W by the hand 3. Thus, the first current value Ia is a current value of the motor current in a case where the hand 3 does not pick up the workpiece W. The second current value Ib is a current value of the motor current after the hand 3 has picked up the workpiece W. In this example, the first current value Ia and the second current value Ib are current values of actual motor currents before and after the hand 3 picks up the workpiece W in a series of transfer actions, that is, in the same transfer actions. The first current value Ia is a current value immediately before the hand 3 picks up the workpiece W, and the second current value Ib is a current value immediately after the hand 3 has picked up the workpiece W. Thus, the first current value Ia and the second current value Ib are current values of motor currents while the hand 3 elevates at a substantially constant speed.

The corrector 67 corrects the second target height Z2 of the hand 3 with the correction amount ΔZ. Specifically, the corrector 67 increases the second target height Z2 by the correction amount ΔZ. More specifically, the corrector 67 corrects the target rotation position of the first electric motor 24a with a rotation amount corresponding to the correction amount ΔZ. That is, the corrector 67 corrects the second target height Z2 after the hand 3 has picked up the workpiece W and before the hand 3 places the workpiece W on the stage 113 in the second box 112.

In step S107, the controller 6 actuates the hold actuator 35 to cause the hand 3 to hold the workpiece W. Since the controller 6 controls the position of the hand 3, the controller 6 knows an approximate timing when the hand 3 passes over the height of the workpiece W. The controller 6 actuates the hold actuator 35 after the hand 3 has passed the height of the workpiece W, that is, after the hand 3 has picked up the workpiece W. It should be noted that the hold actuator 35 may be actuated before the target height of the hand 3 is corrected as long as the hold actuator 35 is actuated after the hand 3 has picked up the workpiece W.

As illustrated in FIG. 7, the motor current to the first electric motor 24a varies

because of pickup of the workpiece W by the hand 3. Specifically, a motor current with which the target rotation position of the first electric motor 24a is achieved increases by the weight of the workpiece W. The amount of this increase of the motor current based on the weight of the workpiece W is the variation amount ΔI of the motor current. The variation amount ΔI of the motor current varies depending on the weight of the workpiece W. As the weight of the workpiece W increases, the variation amount ΔI of the motor current also increases. The variation amount ΔI of the motor current is approximately proportional to the weight of the workpiece W.

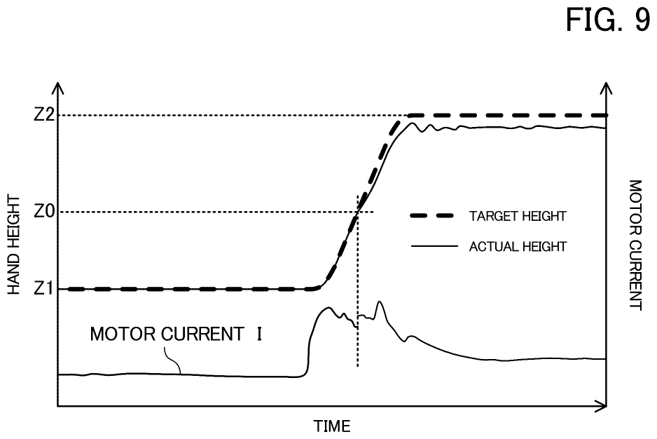

On the other hand, the controller 6 controls the height of the hand 3 using the rotation position of the first electric motor 24a. Thus, the target rotation position of the first electric motor 24a for achieving the target height of the hand 3 is determined in consideration of dimensions, deflection, rattles, and other factors of the robot arm 2 and the hand 3. However, when the hand 3 picks up the workpiece W, the weight of the hand 3 increases apparently by a weight corresponding to the workpiece W. Even at the same rotation position of the first electric motor 24a, deflection, rattles, and other factors of the robot arm 2 and the hand 3 vary and the real height of the hand 3 can vary, depending on whether the hand 3 picks up the workpiece W or not. That is, the real height of the hand 3 corresponding to the rotation position of the first electric motor 24a varies because of pickup of the workpiece W by the hand 3. FIG. 9 is a graph showing the motor current to the first electric motor 24a and the height of the hand 3 during a transfer action in a case where the target height of the hand 3 is not corrected. Since a rotation torque for achieving the target rotation position of the first electric motor 24a increases because of pickup of the workpiece W by the hand 3, the motor current increases in a manner similar to the case in FIG. 7. Although the motor current increases in accordance with the weight of the workpiece W, the target rotation position is not corrected. The first electric motor 24a operates to achieve the target rotation position. However, deflection and rattles of the robot arm 2 and the hand 3 increase in accordance with the weight of the workpiece W, the real height of the hand 3 corresponding to the target rotation position of the first electric motor 24a is lower than that before the workpiece W is picked up. That is, the real height of the hand 3 becomes lower than the target height corresponding to the target rotation position of the first electric motor 24a.

The variation amount of the real height of the hand 3 caused by the weight of the workpiece W is approximately proportional to the weight of the workpiece W. As the weight of the workpiece W increases, the variation amount of the real height of the hand 3 also increases. As described above, the variation amount ΔAI of the motor current is also approximately proportional to the weight of the workpiece W. That is, the variation amount of the real height of the hand 3 depending on the weight of the workpiece W is approximately proportional to the variation amount ΔI of the motor current. Thus, as expressed by Equation (1), the controller 6 obtains the correction amount ΔZ by multiplying the variation amount ΔI of the motor current by a correction factor K. The controller 6 corrects the second target height Z2 to a second target height Z2′ by adding the correction amount ΔZ. The controller 6 adjusts the motor current such that the first electric motor 24a is located at a target rotation position corresponding to the corrected second target height Z2′. As a result, the real height of the hand 3 increases as compared to the case of not correcting the target height, and approaches the second target height Z2 before correction. That is, the corrected second target height Z2′ is a target height for control, and an actual target height of the hand 3 remains at the second target height Z2 before correction. Since the second target height Z2′ increases by the correction, the time for the hand 3 to elevate increases, and a period in which the motor current to the first electric motor 24a is large increases accordingly.

In terms of control, when the hand 3 reaches the corrected second target height Z2′, that is, the rotation position of the first electric motor 24a reaches the target rotation position corresponding to the second target height Z2′, the controller 6 causes the robot 1 to perform second horizontal movement in step S108. In the second horizontal movement, the robot arm 2 moves the hand 3 horizontally from the first box 111 to a position above the stage 113 in the second box 112. The controller 6 controls the second electric motors 24b to thereby move the links 22 and move the hand 3 into the second box 112. As illustrated in FIG. 7, during the second horizontal movement, the motor current to the first electric motor 24a hardly varies. That is, the real height of the hand 3 is still approximately equal to the second target height Z2 before correction.

When the hand 3 moves to the position above the stage 113 in the second box 112, the controller 6 causes the robot 1 to perform a descent action in step S110. In the descent action, the robot 1 moves the hand 3 downward from the corrected second target height Z2′ to the first target height Z1. In this example, in the descent action, the controller 6 causes the robot arm 2 and the hand 3 to perform constant-speed motion in which the hand 3 descends at a constant speed. The controller 6 controls a descending speed of the hand 3 by adjusting the motor current to the first electric motor 24a. FIGS. 7 and 9 do not show the descent action.

Thereafter, as the hand 3 descends, the workpiece W eventually contacts the stage 113. At a timing before the workpiece W contacts the stage 113, the controller 6 stops actuation of the hold actuator 35 and causes the hand 3 to release the workpiece W in step S110. After the hand 3 has released the workpiece W, the workpiece W is transferred from the hand 3 to the stage 113. When the hand 3 descends to the first target height Z1, the transfer action is finished.

Through this transfer action, the target height of the hand 3 in position control is corrected depending on the workpiece W held by the hand 3. Deflection and other factors of the robot arm 2 and the hand 3 depend on at least the weight of the workpiece W. In a case where the robot 1 handles only one type of the workpiece W, the height position of the hand 3 does not vary depending on the workpiece W. Since the controller 6 corrects the target height of the hand 3 depending on the workpiece W, even when the weight of the workpiece W changes, the target height of the hand 3 is appropriately corrected. For example, in a case where the robot system 100 transfers multiple types of workpieces W, the correction amount of the target height of the hand 3 is adjusted depending on the weight of the workpiece W. As a result, position accuracy of the hand 3 can be enhanced for any type of the workpiece W.

In addition, the controller 6 automatically adjusts the correction amount depending on the workpiece W. A user does not need to set the correction amount or other properties again at every change of workpieces W. Specifically, the controller 6 corrects the target height based on variations of the motor current to the first electric motor 24a caused by pickup of the workpiece W by the hand 3. When the hand 3 picks up the workpiece W, the motor current to the first electric motor 24a varies in accordance with the weight of the workpiece W. That is, the motor current to the first electric motor 24a after the hand 3 has picked up the workpiece W reflects the weight of the workpiece W. Since the motor current to the first electric motor 24a can be acquired by the controller 6 during the transfer action, the controller 6 can automatically determine the correction amount of the target height of the hand 3 without an input of the type, weight, or other information of the workpiece W from the user.

The controller 6 also acquires a motor current to the first electric motor 24a before the hand 3 picks up the workpiece W, during the transfer action. The controller 6 acquires an actual motor current before the hand 3 picks up the workpiece W and an actual motor current after the hand 3 has picked up the workpiece W in a series of transfer actions, that is, in the same transfer actions, and based on the variation amounts of these motor currents, determines a correction amount of the target height of the hand 3. Thus, the motor current to the first electric motor 24a before the hand 3 picks up the workpiece W does not need to be input to the controller 6 by the user. In addition, since the actual motor current before the hand 3 picks up the workpiece W and the actual motor current after the hand 3 has picked up the workpiece W are acquired under the same condition, the controller 6 can correct the target height so as to appropriately reflect the weight of the workpiece W.

At this time, the controller 6 causes the robot arm 2 and the hand 3 to perform constant-speed motion in which the height position of the hand 3 changes at a constant speed before and after the hand 3 picks up the workpiece W. That is, it is possible to reduce variations of the motor current to the first electric motor 24a caused by factors other than the weight of the workpiece W before and after the hand 3 picks up the workpiece W. Accordingly, the controller 6 can correct the target height, while more appropriately reflecting the weight of the workpiece W.

### OTHER EMBODIMENTS

In the foregoing section, the embodiment has been described as an example of the technique disclosed in the present application. The technique disclosed here, however, is not limited to this embodiment, and is applicable to other embodiments obtained by changes, replacements, additions, and/or omissions as necessary. Components described in the above embodiment may be combined as a new exemplary embodiment. Components provided in the accompanying drawings and the detailed description can include components unnecessary for solving problems as well as components necessary for solving problems in order to exemplify the technique. Therefore, it should not be concluded that such unnecessary components are necessary only because these unnecessary components are included in the accompanying drawings or the detailed description.

For example, the robot 1 is not limited to application for substrate transfer. The robot 1 is not limited to use in an environment that is clean enough to enable processing of a semiconductor. The robot 1 may be incorporated in, for example, a production line.

The robot 1 is not limited to a horizontal articulated robot. For example, the robot 1 may be a vertical articulated robot. The robot 1 only needs to include a robot arm to which a hand is coupled.

The robot arm 2 does not need to be constituted by the multiple links 22. In the case of dividing the robot arm 2, the number of divided parts of the robot arm 2, that is, the number of links 22, is not limited to three. The robot arm 2 may include two or four or more links 22.

The configuration of the hand 3 is not limited to the configuration described above. For example, holding of the workpiece by the hand 3 is not limited to gripping with nails. For example, the hand 3 can hold the workpiece by suction. The hand 3 can hold the workpiece only by simply supporting the bottom of the workpiece, that is, only placing the workpiece thereon. The hand 3 may grip the workpiece with fingers.

Correction of the target height of the hand 3 is not limited to the method described above. For example, the variation amount of the first electric motor 24a is not limited to a value obtained by the method described above. The motor current is not limited to the moving average value, and may be a value that has not been averaged. The first current value Ia and the second current value Ib are not limited to current values immediately before and immediately after the variation amount reaches the threshold or more. Since the positions of the hand 3 and the workpiece W are generally known, the first current value Ia may be a current value at a predetermined timing before the hand 3 picks up the workpiece W, and the second current value Ib may be a current value at a predetermined timing after the hand 3 has picked up the workpiece W.

The first current value Ia may be a previously acquired value of the motor current to the first electric motor 24a in a case where the hand 3 does not pick up the workpiece W. Since the second current value Ib reflects the weight of the workpiece W, the second current value Ib is acquired in an actual transfer action. In the case of acquiring the first current value Ia beforehand, acquisition conditions for the first current value Ia are preferably close to acquisition conditions for the second current value Ib. Thus, the robot 1 may perform the same action as the transfer action without picking up the workpiece W so that the first current value Ia is acquired at the timing of acquiring the second current value Ib in the transfer action. Accordingly, the first current value Ia and the second current value Ib can be acquired under substantially the same conditions except whether the workpiece W is held or not.

The correction amount ΔZ is not limited to an amount obtained from Equation (1). The controller 6 may previously store a table defining a relationship between the variation amount of the motor current and the correction amount of the target height, in the storage 63, for example. In this case, the controller 6 obtains the correction amount of the target height by comparing the variation amount of the motor current with the table in the storage 63. The controller 6 does not necessarily continuously change the correction amount of the target height in accordance with the variation amount of the motor current. For example, the controller 6 may adjust the correction amount of the target height stepwise in accordance with the variation amount of the motor current. Specifically, the controller 6 may prepare different correction amounts of the target height to select one of the correction amounts in accordance with the variation amount of the motor current.

The timing of correcting the target height of the hand 3 may be set at any time. In the example described above, when the variation amount of the motor current reaches the threshold or more, the controller 6 obtains the correction amount ΔZ and corrects the target height of the hand 3. For example, the controller 6 may correct the second target height Z2 to the second target height Z2′ after controlling the height of the hand 3 to the second target height Z2 so that the hand 3 is located at the second target height Z2′.

The flowchart is merely an example. The steps in the flowchart may be changed, replaced, added, omitted, or the like as appropriate. Further, the order of steps in the flowchart may be changed or serial processing may be performed in parallel. For example, in the flowchart of the transfer action (FIG. 6), correction of the target height in step S106 and the holding action in step S107 may be performed in parallel, or may be performed in the reversed order. The order of descending in step S109 and releasing in step 110 may be replaced.

Functions performed by constitutional elements described herein may be implemented in circuitry or processing circuitry including a general-purpose processor, an application-specific processor, an integrated circuit, an application specific integrated circuit (ASIC), a central processing unit (CPU), conventional circuitry, and/or a combination thereof programmed to perform the functions described herein. A processor includes transistors and other circuits, and is regarded as circuitry or arithmetic circuitry. A processor may be a programmed processor that performs programs stored in a memory.

Circuitry, a unit, and means herein are hardware that is programmed to perform or performs the described functions. The hardware may be any hardware disclosed herein, or any hardware programmed or known to perform the functions described.

If the hardware is a processor considered to be of a type of circuitry, the circuitry, means, or a unit is a combination of hardware and software used to configure the hardware and/or the processor.

The techniques of the present disclosure described above are summarized as follows.
[1] A robot system 100 includes: a robot 1 including a hand 3 that holds a workpiece W, and a robot arm 2 to which the hand 3 is coupled; and a controller 6 that moves the robot arm 2 to perform position control of the hand 3, and the controller 6 corrects a target height of the hand 3 in the position control depending on the workpiece W held by the hand 3.

In this configuration, deflection of the robot arm 2 and the hand 3 caused by pickup of the workpiece W varies depending on the weight of the workpiece W. That is, the height of the hand 3 can vary depending on the weight of the workpiece W. The variation of the height of the hand 3 depending on the weight of the workpiece W can be reduced by correcting the target height of the hand 3 depending on the workpiece W. Even with variations in the weight of the workpiece W, position accuracy for the height of the hand 3 can be stabilized. As a result, position accuracy of the height of the hand 3 can be enhanced.
[2] In the robot system 100 of [1], the robot arm 2 includes a first electric motor 24a that changes a height position of the hand 3, and the controller 6 corrects the target height based on variation of a motor current to the first electric motor 24a caused by pickup of the workpiece W by the hand 3.

In this configuration, when the hand 3 picks up the workpiece W, the motor current to the first electric motor 24a varies in accordance with the weight of the workpiece W. That is, variation of the motor current to the first electric motor 24a caused by pickup of the workpiece W reflects the weight of the workpiece W. The target height of the hand 3 can be corrected depending on the workpiece W by correcting the target height of the hand 3 based on the variation of the motor current.
[3] In the robot system 100 of [1] or [2], the controller 6 corrects the target height based on a variation amount between a motor current to the first electric motor 24a previously acquired in a case where the hand 3 does not pick up the workpiece W and an actual motor current to the first electric motor 24a after the hand 3 has picked up the workpiece W.

In this configuration, the motor current to the first electric motor 24a, that is, the first current value Ia, in a case where the hand 3 has not picked up the workpiece W is acquired beforehand. On the other hand, as the motor current to the first electric motor 24a after the hand 3 has picked up the workpiece W, that is, the second current value Ib, a current value of an actual motor current is acquired during position control of the hand 3. The second current value Ib varies depending on the weight of the workpiece W picked up by the hand 3. On the other hand, the first current value Ia is not affected by the workpiece W. Thus, the first current value Ia can be acquired beforehand. Accordingly, processes in correction in actual position control can be made easy.
[4] In the robot system 100 of [1] or [2], the controller 6 corrects the target height based on a variation amount between an actual motor current before the hand 3 picks up the workpiece W and an actual motor current after the hand 3 has picked up the workpiece W in a series of actions in which the hand 3 picks up and transfers the workpiece W under the position control.

In this configuration, the motor current to the first electric motor 24a in the case where the hand 3 has not picked up the workpiece W, that is, the first current value Ia, and the motor current to the first electric motor 24a in the case where the hand 3 has picked up the workpiece W, that is, the second current value Ib, are also acquired in a series of actual transfer actions. In this case, the current value of the motor current does not need to be acquired beforehand, a correction process is made easy in this regard.
[5] In the robot system 100 in any one of [2] to [4], the controller 6 causes the robot arm 2 and the hand 3 to perform constant-speed motion in which a height position of the hand 3 changes at a constant speed before and after the hand 3 picks up workpiece W, and corrects the target height based on the variation amount between the actual motor current before the hand 3 picks up the workpiece W and the actual motor current after the hand 3 has picked up the workpiece W in the constant-speed motion.

In this configuration, the motor current to the first electric motor 24a is stabilized before and after the hand 3 picks up the workpiece W. Accordingly, variation of the motor current to the first electric motor 24a caused by pickup of the workpiece W by the hand 3 can be acquired with stability. That is, the first current value Ia and the second current value Ib can be acquired with a relatively stable state of the motor current. Accordingly, the height position of the hand 3 can be accurately corrected based on variation of the motor current.
[6] In the robot system 100 of [2], after the hand 3 has picked up the workpiece W, the controller 6 corrects the target height.

In this configuration, the target height of the hand 3 is corrected after the hand 3 has picked up the workpiece W. That is, the motor current to the first electric motor 24a can vary before and after the hand 3 picks up the workpiece W. Thus, the target height is corrected after the hand 3 has picked up the workpiece W.
[7] In the robot system 100 of any one of [1] to [6], the robot arm 2 includes links 22 coupled to one another to be rotatable horizontally.

In this configuration, the robot 1 is a so-called horizontal articulated robot. The correction of the target height of the hand 3 described above can further enhance position accuracy of the height of the hand 3 in the horizontal articulated robot.
[8] In the robot system 100 of any one of [1] to [6], the hand 3 holds a substrate as the workpiece W.

In this configuration, the robot 1 transfers the substrate. For example, handling of semiconductor wafers requires high position accuracy. In the robot 1, the real height of the hand 3 is appropriately adjusted in accordance with the weight of the substrate such as a semiconductor wafer, allowing the substrate to be transferred with high position accuracy.
[9] In the robot system 100 of any one of [1] to [6], the hand 3 holds any one of a plurality of types of workpieces W.

In this configuration, the robot 1 handles multiple types of workpieces W. The hand 3 holds the workpiece W selected from the multiple types of workpieces W. Since the controller 6 corrects the target height of the hand 3 depending on the workpiece W, even if the hand 3 holds different types of workpieces W, degradation of position accuracy of the height of the hand 3 can be suppressed.

[10] A robot control method includes: moving a robot arm 2 to which a hand that holds a workpiece W is coupled to perform position control of the hand 3; and correcting a target height of the hand 3 in the position control depending on the workpiece W held by the hand 3.

In this configuration, the target height of the hand 3 is corrected depending on the workpiece W to thereby reduce variations of the height of the hand 3 depending on the weight of the workpiece W. Even with variations in the weight of the workpiece W, position accuracy for the height of the hand 3 can be stabilized. As a result, position accuracy of the height of the hand 3 can be enhanced.
[11] A robot control program 63a for causing a controller 6 (computer) to perform the function of controlling a robot 1 including a hand 3 that holds a workpiece W and a robot arm 2 to which the hand 3 is coupled, the program causing the computer 6 to perform the functions of: moving the robot arm 2 to perform position control of the hand 3; and correcting a target height of the hand 3 in the position control depending on the workpiece W held by the hand 3.

In this configuration, the target height of the hand 3 is corrected depending on the workpiece W to thereby reduce variations of the height of the hand 3 depending on the weight of the workpiece W. Even with variations in the weight of the workpiece W, position accuracy for the height of the hand 3 can be stabilized. As a result, position accuracy of the height of the hand 3 can be enhanced.

1. A robot system comprising:
a robot including a hand that holds a workpiece, and a robot arm to which the hand is coupled; and
a controller that moves the robot arm to perform position control of the hand, wherein
the controller corrects a target height of the hand in the position control depending on the workpiece held by the hand.

2. The robot system according to claim 1, wherein
the robot arm includes an electric motor that changes a height position of the hand, and
the controller corrects the target height based on variation of a motor current to the electric motor caused by pickup of the workpiece by the hand.

3. The robot system according to claim 2, wherein
the controller corrects the target height based on a variation amount between a motor current previously acquired in a case where the hand does not pick up the workpiece and an actual motor current after the hand has picked up the workpiece.

4. The robot system according to claim 2, wherein
the controller corrects the target height based on a variation amount between an actual motor current before the hand picks up the workpiece and an actual motor current after the hand has picked up the workpiece in a series of actions in which the hand picks up and transfers the workpiece under the position control.

5. The robot system according to claim 4, wherein
the controller
causes the robot arm and the hand to perform constant-speed motion in which a height position of the hand changes at a constant speed before and after the hand picks up the workpiece, and
corrects the target height based on the variation amount between the actual motor current before the hand picks the workpiece and the actual motor current after the hand has picked up the workpiece in the constant-speed motion.

6. The robot system according to claim 2, wherein
after the hand has picked up the workpiece, the controller corrects the target height.

7. The robot system according to claim 1, wherein
the robot arm includes links coupled to one another to be rotatable horizontally.

8. The robot system according to claim 1, wherein
the hand holds a substrate as the workpiece.

9. The robot system according to claim 1, wherein
the hand holds any one of a plurality of types of workpieces. 10, (Original) A robot control method comprising:
moving a robot arm to which a hand that holds a workpiece is coupled to perform position control of the hand; and
correcting a target height of the hand in the position control depending on the workpiece held by the hand.

11. A non-transitory storage medium storing a robot control program for causing a computer to perform the function of controlling a robot including a hand that holds a workpiece and a robot arm to which the hand is coupled, the program causing the computer to perform the functions of:
moving the robot arm to perform position control of the hand; and
correcting a target height of the hand in the position control depending on the workpiece held by the hand.
